(19) United States
(12) Patent Application Publication
(10) Pub. No.: US 2026/0072062 A1
(43) Pub. Date: Mar. 12, 2026

(54) LOCKING DEVICE FOR A COVER ASSEMBLY

(71) Applicant: SAGEMCOM ENERGY & TELECOM SAS, Bois-Colombes (FR)

(72) Inventors: Matthieu BROSSARD, BOIS-COLOMBES (FR); Charles CHEVROT, BOIS-COLOMBES (FR)

(21) Appl. No.: 19/319,547

(22) Filed: Sep. 4, 2025

(30) Foreign Application Priority Data
Sep. 6, 2024 (FR) 2409467

(51) Int. Cl. G01R 22/06; E05C 1/00; E05C 1/10

(52) U.S. Cl. CPC G01R 22/065; E05C 1/004; E05C 1/10

(57) ABSTRACT

The present invention relates to a cap assembly comprising a main wall and a cover, adapted to cooperate with each other, the cap assembly comprising a locking device configured to lock the cover in position on the main wall, the locking device comprising at least: an actuator on the main wall and comprising at least one actuating rib and at least one elastically deformable member, and a locking member projecting from the cover and configured at least to lock said cover in position with respect to the main wall.

### CROSS-REFERENCE TO RELATED APPLICATIONS

The present application claims priority to French Application No. 2409467 filed with the French National Institute of Industrial Property (INPI) on September 6, 2024, and entitled “DISPOSITIF DE VERROUILLAGE D’UN ENSEMBLE DE CAPOT,” which is incorporated herein by reference in its entirety for all purposes.

### TECHNICAL FIELD OF THE INVENTION

The present invention relates to a cover assembly or cap assembly comprising a locking device suitable for securing a cover to a main wall.

### TECHNICAL BACKGROUND

When two parts are to be secured together, it is common practice to use a third part, such as a screw, which is independent of the parts to be secured, in order to hold them in position with respect to each other.

For example, in the field of electric meter installations, it is common for a cover, or terminal cover, to be secured to a cap via a screw, such as a quarter-turn screw. In this case, a user must position the cover over the cap and then must perform a screwing or rotating operation of the screw by a quarter turn. Thus, when a user wants to detach the cover from the cap, he must first unscrew the screw and then unhook the cover from the cap.

The aim of the present invention is to provide an alternative to existing solutions for securing two parts together, for example in an electric meter installation, by not using an independent third part.

The aim of the invention is thus to reduce the complexity of the assembly between two parts, by designing a locking device directly integrated into the parts to be secured together.

### SUMMARY OF THE INVENTION

The invention provides a cap assembly (ie a cover assembly) comprising a main wall and a cover, adapted to cooperate with each other, the cap assembly comprising a locking device configured to lock the cover in position on the main wall, the locking device comprising at least:

- An actuator on the main wall and comprising at least one actuating rib and at least one elastically deformable member translationally linked to each other,

the actuating rib extending across a through-aperture formed in the main wall, and

the actuator being movable in translation with respect to the main wall so that the actuating rib moves across the aperture between a closed position of the locking device wherein the elastically deformable member is in a decompressed state, and an open position of the locking device wherein the elastically deformable member is in a compressed state,

- A locking member projecting from the cover and configured at least to lock said cover in position with respect to the main wall when the actuating rib of the actuator is in the closed position of the locking device.

According to other features of the invention:

- the actuator comprises a strip (for example forming a blade or a board) from which the actuating rib projects, the strip being secured to the elastically deformable member by at least one retaining arm extending transversely from the strip, the elastically deformable member or spring being secured to the retaining arm;

- at least two retaining members project from the main wall and so as to lock the actuator in position against the main wall and to allow the translational movement of the actuator with respect to the main wall;

- the main wall comprises a through-bore configured to receive the locking member;

- the locking member comprises at least one guide edge (for example forming a guide surface) extending in a plane intersecting a common plane of the actuator, the at least one guide edge being configured to move the actuating rib from the closed position of the locking device to the open position of the locking device when the locking member is inserted into the bore;

- the locking member comprises at least one retaining edge (for example forming a retaining surface) configured to automatically move the actuating rib from the open position of the locking device to the closed position of the locking device when the locking member is inserted into the bore, so as to lock the cover in position with respect to the main wall;

- the strip comprises a beveled edge (for example forming a beveled surface) configured to be in planar contact with the at least one guide edge of the locking member when the locking member is inserted into the bore;

- the locking member comprises at least one contact edge (for example forming a contact surface) configured to be in planar contact with the beveled edge of the strip when the locking member is inserted into the bore and the actuating rib is in the closed position of the locking device;

- the cover comprises a complementary aperture configured to extend opposite or facing the aperture in the main wall when the cover is assembled on the main wall and so that the actuating rib extends through the complementary aperture;

- the actuator is pivotally mounted with respect to the main wall by means of at least one elastic hinge extending between the at least one elastically deformable member and the main wall, and so that the actuator is capable of pivoting about a hinge axis with respect to the main wall;

- the actuator is integral with the main wall and the locking member is integral with the cover;

- the cap assembly is obtained by a plastic injection process.

The invention also relates to an electric meter installation comprising an electric meter and at least one cap assembly according to any of the preceding features.

### BRIEF DESCRIPTION OF THE FIGURES

Further features and advantages of the invention will become apparent from the following detailed description, which may be understood with reference to the attached drawings wherein:

FIG. 1A is a general perspective view of an electric meter installation comprising a cap assembly composed of a main wall, a cover and a locking device;

FIG. 1B is a general exploded view of the electricity meter installation of FIG. 1A showing the cover detached from the main wall;

FIG. 2 is a schematic perspective view of the main wall of the cap assembly of FIG. 1A and an actuator of the locking device of FIG. 1A formed on the main wall, the locking device comprising at least one spring depicted in a decompressed state;

FIG. 3 is a schematic perspective view of the main wall of the cap assembly of FIG. 1A and the actuator of the locking device of FIG. 1B formed on the main wall, the locking device comprising at least the spring depicted in a compressed state;

FIG. 4 is a schematic perspective view of an outer face of the main wall of FIG. 1A showing an actuating rib of the actuator which projects into an aperture in the main wall;

FIG. 5 is a schematic front view of the outer face of the main wall of FIG. 1A showing the actuating rib of the actuator which projects into the aperture in the main wall, and showing a U-shaped through-bore of the main wall;

FIG. 6 is a schematic perspective view of the cover of FIG. 1A comprising a locking member of the locking device of FIG. 1A and a complementary aperture;

FIG. 7 is a schematic side view of the cover of FIG. 6;

FIG. 8 is a schematic perspective view of the cover assembled on the main wall by means of the locking device;

FIG. 9 is a schematic perspective view of the main wall on which the actuator of the locking device is formed in a raised position, following a plastic injection manufacturing process;

FIG. 10A is a schematic perspective view of the main wall of the cap assembly of FIG. 1A and of the actuator of the locking device of FIG. 1A formed on the main wall, the locking device comprising two springs shown in a decompressed state;

FIG. 10B is a schematic front view of the outer face of the main wall showing the actuating rib extending through the aperture in the main wall in a closed position of the locking device and the U-shaped bore;

FIG. 11A is a schematic longitudinal and vertical cross-sectional view of the cap assembly of FIG. 1A showing the locking member during insertion thereof into the U-shaped bore of the main wall;

FIG. 11B is a schematic front view of the outer face of the main wall and of the cover, showing the actuating rib extending through the aperture and the complementary aperture of the main wall and the cover, the actuating rib being in a closed position of the locking device;

FIG. 12A is a schematic longitudinal and vertical cross-sectional view of the cap assembly of FIG. 1A showing the locking member during insertion thereof into the U-shaped bore of the main wall;

FIG. 12B is a schematic front view of the outer face of the main wall and cover, showing the actuating rib extending through the aperture and the complementary aperture of the main wall and the cover, the actuating rib being in an open position of the locking device;

FIG. 13A is a schematic longitudinal and vertical cross-sectional view of the cap assembly of FIG. 1A showing the locking member locked in position by the actuator in the U-shaped bore of the main wall;

FIG. 13B is a schematic front view of the outer face of the main wall and the cover, showing the actuating rib extending through the aperture and the complementary aperture of the main wall and the cover, the actuating rib being in the closed position of the locking device.

### DETAILED DESCRIPTION OF THE INVENTION

In the following description, identical, similar or analogous elements will be referred to by the same reference numbers.

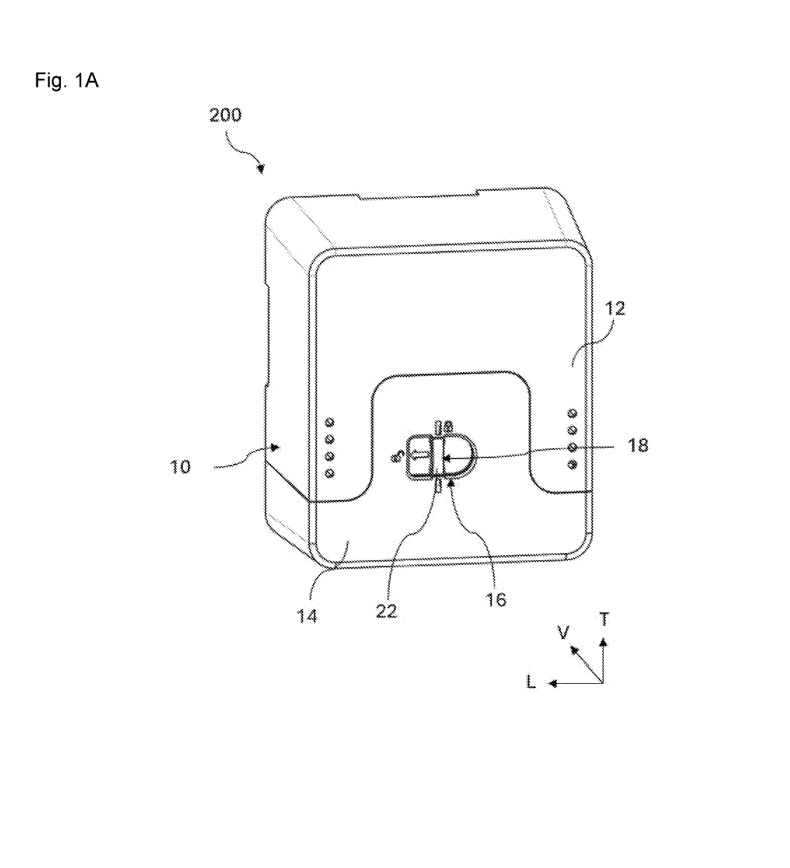

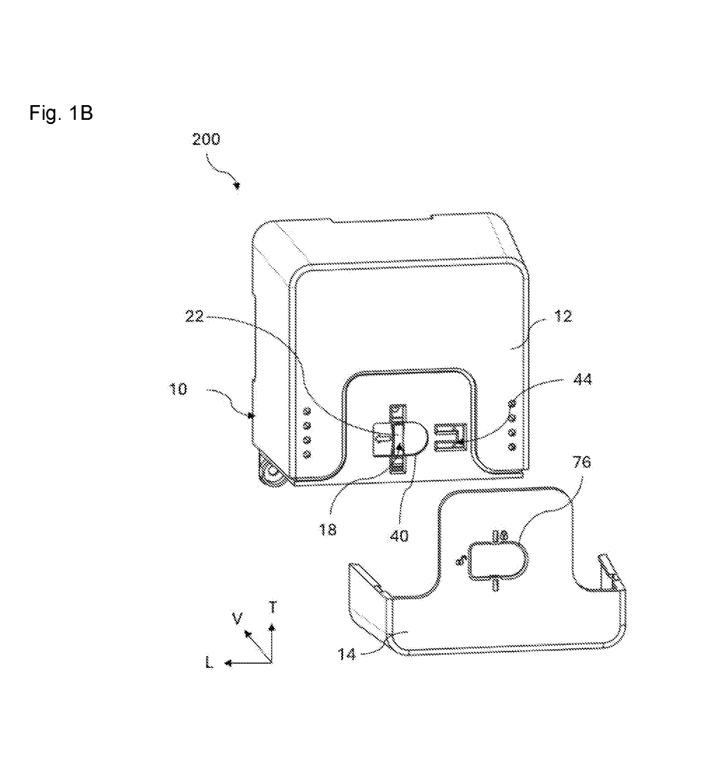

FIGS. 1A and 1B show a cap assembly 10 composed of a main wall 12 and a cover 12 which are adapted to cooperate with each other and locked in position with respect to each other by means of a locking device 16 of the cap assembly 10.

More specifically, the locking device 16 is configured to lock the cover 14 in position on the main wall 12.

By way of a non-limiting example, the cap assembly 10 herein forms part of an electric meter installation 200, the main wall 12 of which may form a cap of the electric meter and the cover 14 of which may be a terminal cover for this electric meter cap, arranged at least partly overlapping the main wall 12.

The cap assembly 10 is thus configured to isolate, at least visually, the electric meter installation 200 from the external environment.

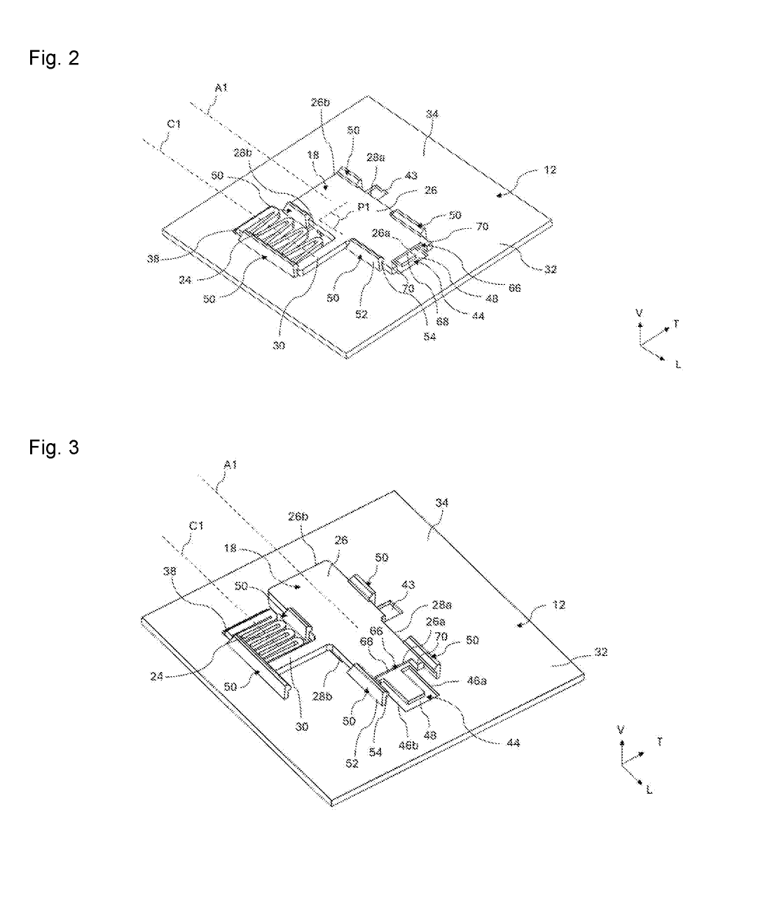

In the remainder of this description, it should thus be borne in mind that the main wall 12 and the cover 14 are depicted in a reduced and purely schematic form. Also, the depiction of the main wall 12 and the cover 14 in the figures does not constitute a definite and exclusive form thereof. Additionally, FIGS. 2 to 13B of the present application identify a part of the main wall 12 and a part of the cover 14 at which the locking device 16 secures them together.

Thus, the main wall 12 and the cover 14 depicted as quadrilateral-shaped plates are provided purely by way of illustration and without limitation.

It should also be borne in mind that, initially, the description will focus on explaining the main wall, the cover and the locking device separately, and then, in a second stage, their cooperation with each other will be the subject of a detailed description.

With reference to the example shown in FIGS. 2 to 7, the locking device 16 of the cap assembly 10 comprises at least one actuator 18 and a locking member 20.

As can be seen in FIGS. 2 to 5, the actuator 18 of the locking device 16 comprises at least one actuating rib 22 and at least one elastically deformable member 24, translationally linked to each other.

In the shown and non-limiting example, the elastically deformable member is a flat spring 24.

As can be seen in FIGS. 2, 4 and 5, the actuating rib 22 protrudes from a strip 26 which itself extends along a main longitudinal L axis of elongation A1 between a first longitudinal end 26a and a second longitudinal end 26b.

The strip 26 herein has the shape of a quadrilateral, with two lateral sides 28a, 28b defined which extend longitudinally between the first longitudinal end 26a and the second longitudinal end 26b of the strip 26.

As shown in FIG. 2, a retaining arm 30 extends from one of the transverse sides 28a, 28b of the strip 26, herein the second transverse side 28b, and along an axis perpendicular to the main axis of elongation A1 of the strip 26.

As shown in FIG. 2, the spring 24 of the actuator 18 extends from the retaining arm 30.

This therefore means that the strip 26 carrying the actuating rib 22 and the spring 24 are integral with each other via the retaining arm 30.

A compression axis C1 of the spring 24 is defined, along which the spring 24 can switch between a state of maximum compression seen in FIG. 3, and a state of maximum decompression seen in FIG. 2.

The compression axis C1 of the spring 24 is herein parallel to the main elongation axis A1 of the strip 26.

Thus, the strip 26 carrying the actuating rib 22 and the spring 24 are integral with each other such that the displacement of the spring 24 between its compressed state and its decompressed state along its compression axis C1 results in the displacement of the strip 26 along its main axis of elongation A1, as seen in FIGS. 2 and 3.

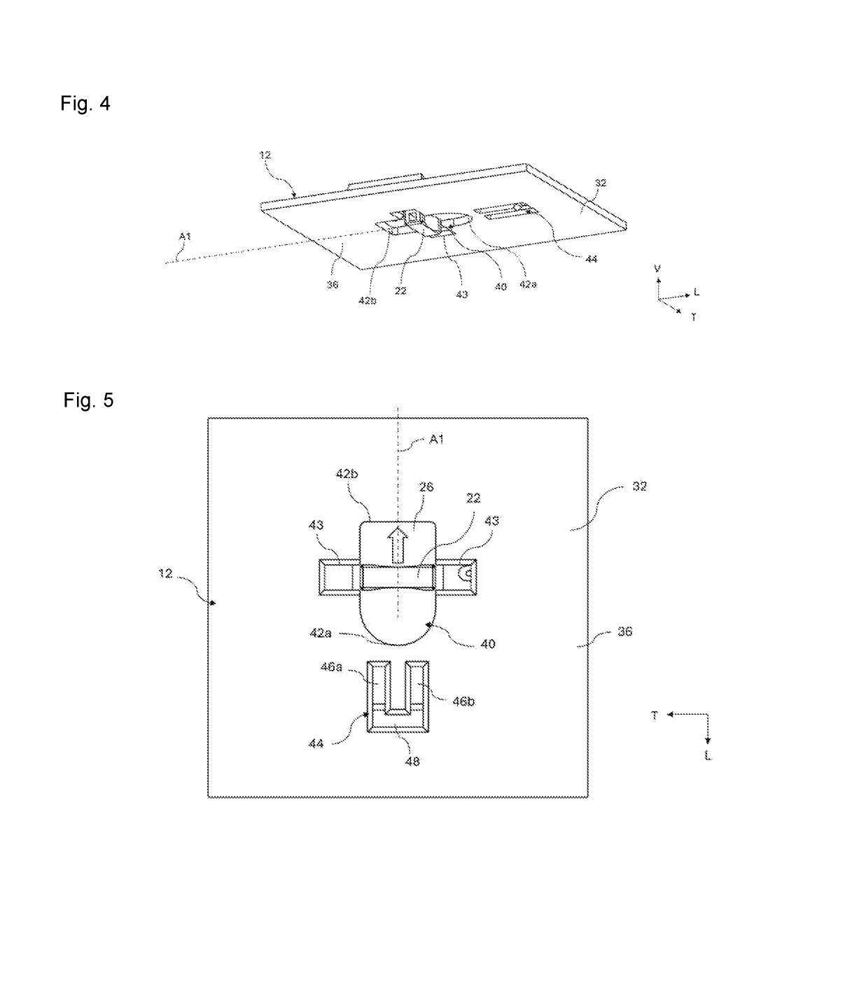

It is further understood that the strip 26, the retaining arm 30 and the spring 24 extend in a common plane P1, seen in FIG. 2, which is defined as longitudinal L and transverse T and that the actuating rib 22 extends in a main plane orthogonal to this common plane P1, as seen in FIG. 4.

The main wall 12 of the cap assembly 10 comprises a flat base 32 which is defined as extending in a main longitudinal plane L and transverse plane T of the base 32.

Herein, the longitudinal axis L is parallel to the main elongation axis A1 of the strip 26 and the compression axis C1 of the spring 24.

An inner face 34 and an outer face 36 of the base 32 of the main wall 12 are also defined, opposite each other along a vertical axis V of the base 32.

It should be noted that the notion of inner and outer are to be considered when the main wall 12 is used for example to cover an electric meter as shown in FIGS. 1A and 1B, the outer face then being the face extending away from the electric meter when the inner face constitutes a face invisible to the user, i.e. turned towards the electric meter under these same conditions.

As seen in FIG. 2, the actuator 18 is mounted against one of the faces of the main wall 12.

More precisely and considering the shown example, the actuator 18 is mounted against the inner face 34 of the base 32 of the main wall 12.

Notably, the spring 24 of the actuator 18 is integral with the base 32 via an elastic hinge 38.

The elastic hinge 38 extends notably between the inner face 34 of the base 32 and an end of the spring 24 opposite to the retaining arm 30 along its compression axis C1.

The use and the function of the elastic hinge 38 will be explained later in the description, notably when describing the assembly process for the cap assembly.

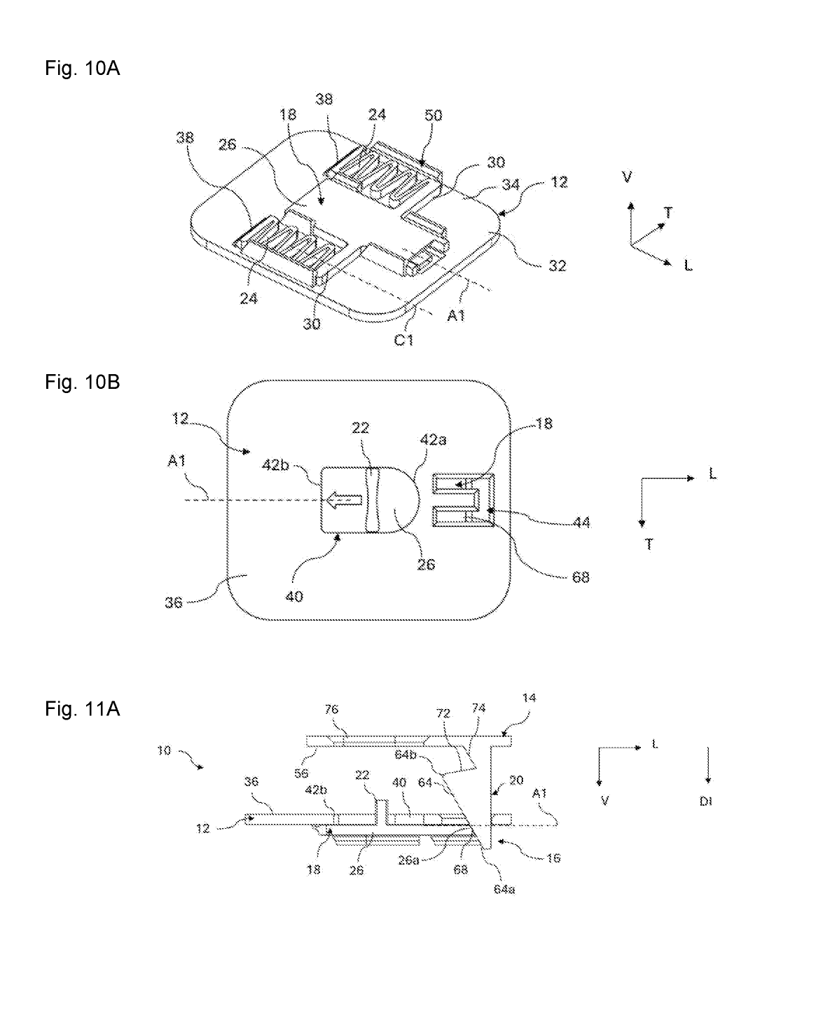

According to another non-limiting example and seen in FIG. 10A, the actuator 18 may comprise two springs 24 which each extend from a separate retaining arm 30.

More precisely, a retaining arm 30 extends perpendicularly from each of the lateral sides 28a, 28b of the strip 26 by being aligned along a transverse axis T.

Thus, each of the two springs 24 extends along a separate compression axis from one of the retaining arms 30 by being connected to the inner face 34 by a elastic hinge 38.

In the remainder of the description, it should be assumed that the detailed features apply to the cap assembly irrespective of whether its actuator comprises one or two springs.

As can be seen in FIGS. 4 and 5, the base 32 of the main wall 12 comprises a through-aperture 40.

The aperture 40 of the base 32 of the main wall 12 extends mainly along the main axis of elongation A1 of the strip 26 of the actuator 18 between a first edge 42a and a second edge 42b, opposite each other along the main axis of elongation A1 of the strip 26.

In the shown and non-limiting example, the first edge 42a of the aperture 40 has a rounded shape and the second edge 42b of the aperture 40 has a rectilinear shape.

The base 32 of the main wall 12 also comprises a through-bore 44, distinct from the through-aperture 40.

As seen in FIG. 5, the aperture 40 and the bore 44 are aligned along a longitudinal axis L of the main wall 12, parallel to the main axis of elongation A1 of the strip 26.

According to the example of the invention, the aperture 40 is dimensioned such that it is traversed at least in part by the actuating rib 22 projecting from the strip 26 of the actuator 18.

In other words, the actuating rib 22 of the actuator 18 extends through the aperture 40 formed in the base 32 of the main wall 12.

More precisely, the actuating rib 22 and the aperture 40 are configured to allow the translational movement of the actuating rib 22 through the aperture 40 according to the compressed and decompressed state of the spring 24 referred to previously.

It is understood from the foregoing that the displacement of the actuating rib 22 through the aperture 40 of the base 32 takes place along the main axis of elongation A1 of the strip 26 of the actuator 18.

A position of the actuating rib 22 is then defined between a closed position of the locking device 16, seen in FIGS. 2, 4 and 11B, when the spring 24 is in its decompressed state seen in FIG. 2, and an open position of the locking device 16, seen in FIG. 12B, when the spring 24 is in its compressed state seen in FIG. 3.

It should be noted that the closed position of the locking device 16 corresponds to a neutral position in which the actuator 18 and more particularly the spring 24 is not subject to any external stress.

As shown in FIG. 10B, in the closed position of the locking device 16, the actuating rib 22 extends at a non-zero longitudinal distance from the first edge 42a and from the second edge 42b of the aperture 40.

In the open position of the locking device 16 seen in FIGS. 12A and 12B, the actuating rib 22 extends substantially in longitudinal abutment against the second edge 42b of the aperture 40, then forming an abutment edge.

As can be seen in FIG. 5, lateral orifices 43 extend transversely on both sides of the aperture 40 formed in the base 32.

The function of the lateral orifices 43 will be explained in the detailed description below.

According to the shown example and particularly seen in FIG. 5, the bore 44 of the base 32 of the main wall 12 is U-shaped.

In accordance with the shown example of the bore 44, two branches 46a, 46b of the U-shape are defined, connected to each other by a base 48 of the U-shape and defining the U-shape of the bore 44.

As can be seen in FIG. 2, in the decompressed state of the spring 24, corresponding to the position of the actuating rib wherein the locking device is in its closed position, the strip 26 carrying the actuating rib is dimensioned such that it extends so as to overlap the aperture formed in the base 32 of the main wall 12 and partly overlaps the bore 44.

More precisely and in accordance with the example shown in FIG. 2, in the decompressed state of the spring 24, the strip 26 is dimensioned such that it only overlaps at least in part the branches 46a, 46b of the U-shape of the bore 44.

Furthermore, in the compressed state of the spring 24, seen in FIG. 3, corresponding to the position of the actuating rib wherein the locking device is in its open position, the strip 26 is dimensioned such that it extends so as to overlap the aperture and so that the bore 44 is completely uncovered by the strip 26.

Thus it is understood that in the compressed and decompressed state of the spring 24 of the actuator 18, the base 48 of the U-shape is uncovered by the strip 26 of the actuator 18.

Furthermore, the bore 44 and notably the branches 46a, 46b of its U-shape are positioned and dimensioned such that the more the spring 24 is compressed along its compression axis C1, the more the branches 46a, 46b of the U-shape of the bore 44 are uncovered by the strip 26.

Herein, in the state of maximum compression of the spring 24, seen in FIG. 3, the branches 46a, 46b of the U-shape of the bore 44 are completely uncovered by the strip 26.

The function of the bore 44 will be explained in the detailed description below.

As can be seen in FIGS. 2 and 3, the base 32 of the main wall 12 comprises means 50 for holding the actuator 18 in position with respect to the main wall 12.

More precisely, the retaining members 50 are configured to maintain the actuator 18 overlapping the inner face 34 of the base 32 of the main wall 12 as described hereinbefore.

As seen in FIGS. 2 and 3, the retaining members 50 extend in a vertical projection from the inner face 34 of the base 32.

The retaining members 50 also extend along the longitudinal axis L of the base 32 of the main wall 12.

The retaining members 50 each comprise a tab 52 at the end of which extends a thickening 54 configured to lock the actuator 18 in position against the inner face 34.

It is notably understood that the retaining members 50 are configured such that the actuator 18 is engaged between the inner face 34 of the base 32 and the thickening 54 of the retaining members 50.

The thickenings 54 of the retaining members 50 notably each form a shoulder facing the inner face 34 of the base 32 of the main wall 12 and configured to form a vertical abutment for the actuator 18 engaged in the retaining members 50.

According to the example shown in FIGS. 2 and 3, two pairs of retaining members 50 extend on both sides of the aperture 40 and the bore 44 formed in the base 32 of the main wall 12 and such that they cooperate with the strip 26 of the actuator 18.

More precisely, at least a part of each lateral side 28a, 28b of the strip 26 is vertically engaged between the shoulders formed by the thickenings 54 of the retaining members 50 and the inner face 34 of the base 32 of the main wall 12.

A retaining member 50 also extends longitudinally along the spring 24 and vertically locks the spring 24 between the shoulder formed by the thickening 54 of the retaining member 50 and the inner face 34 of the base 32.

It is thus understood that the tab 52 of each of the retaining members 50 forms a means of locking the actuator 18 in the transverse position and that the shoulders formed by the thickenings 54 of the retaining members 50 form means of locking the actuator 18 in the vertical position, with respect to the main wall 12.

Furthermore and as seen in FIGS. 2 and 3, the retaining members 50 are configured to allow the translational movement of the actuator 18 with respect to the main wall 12 according to the compressed and decompressed states of the spring 24 mentioned previously.

More precisely, the retaining members 50 arranged on both sides of the aperture 40 and of the bore 44 are arranged such that they form longitudinal abutments of the actuator 18 during its translational movement along the main axis of elongation A1 of the strip 26.

Even more precisely, the retaining members 50 extend in such a way that at least one of the retaining members 50 forms a longitudinal abutment for maximum compression of the spring 24 as seen in FIG. 3 and at least one other retaining member 50 forms a longitudinal abutment for maximum decompression of the spring 24 as seen in FIG. 2.

The retaining members 50 therefore act both as means of locking the actuator 18 in a transverse and vertical position with respect to the base 32 of the main wall 12, while allowing and guiding the translational movement of the actuator 18 along the longitudinal axis L of the base 32 of the main wall 12 and the maximum compression and decompression of the spring(s) 24.

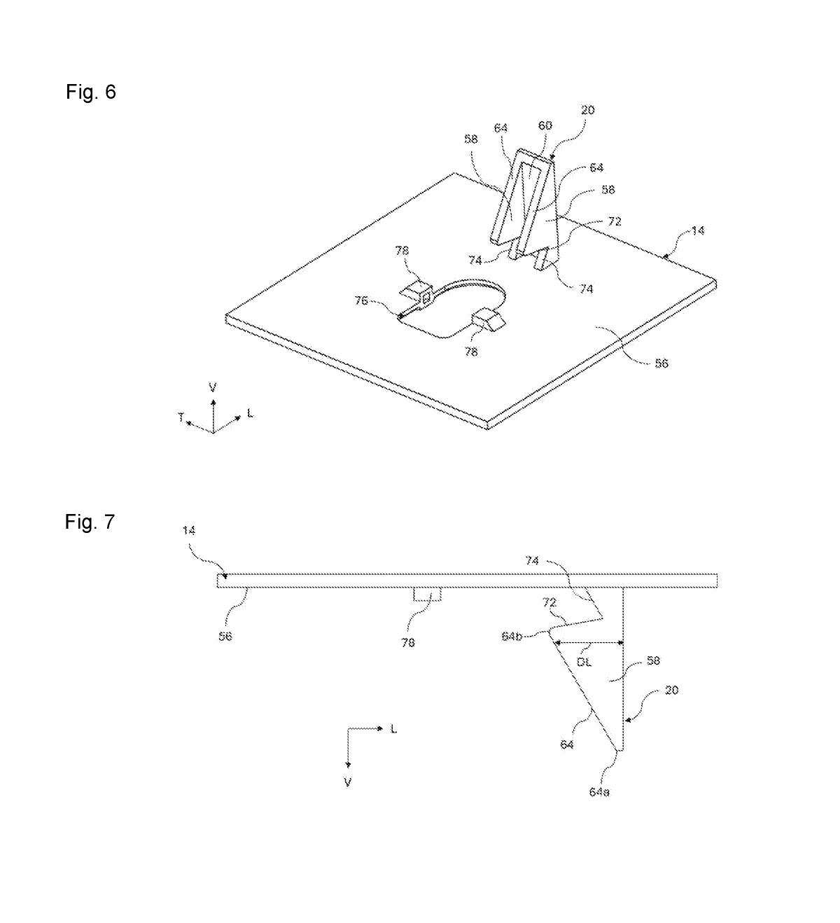

As seen in FIG. 6, the cap assembly 10 also comprises the locking member 20 formed on the cover 14.

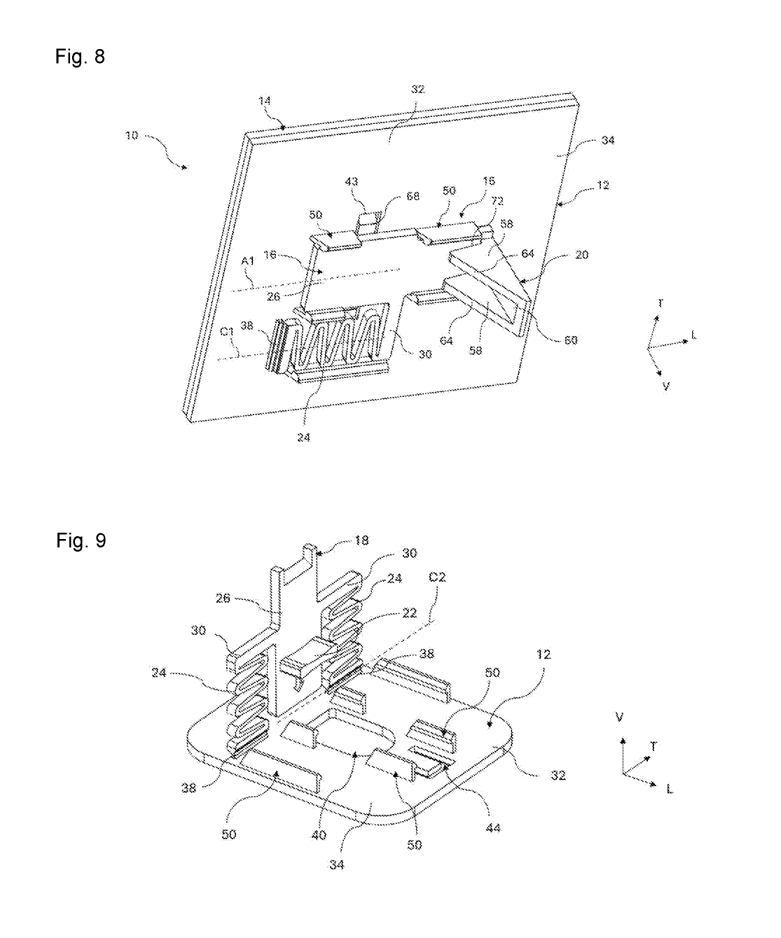

The locking member 20 projects notably from a contact face 56 of the cover 14, the contact face 56 being intended to be in contact with the outer face 36 of the main wall 12 in an assembly position of the cap assembly 10, as seen in FIG. 8.

The longitudinal L, transverse T and vertical V axes of the main wall 12 and of the cover 14 are assumed to coincide when they are assembled via the locking device 16.

The locking member 20 comprises herein and without limitation two vertical walls 58 which each extend in a distinct vertical V and longitudinal L plane, from the contact face 56 of the cover 14 and facing each other along a transverse axis T.

Thus, the two vertical walls 58 extend at a non-zero distance from each other considering a transverse axis T of the cover 14.

The two vertical walls 58 are also connected to each other by a connecting wall 60 which extends from the contact face 56 of the cover 14, in a vertical V and transverse T plane.

It is thus understood that the connecting wall 60 and the vertical walls 58 of the locking member 20 have a U-shaped arrangement in vertical projection on a longitudinal L and transverse T plane of the locking member 20.

Thus and according to the example depicted, the locking member 20 and the bore 44 have a complementary U-shape in longitudinal section L and transverse T section.

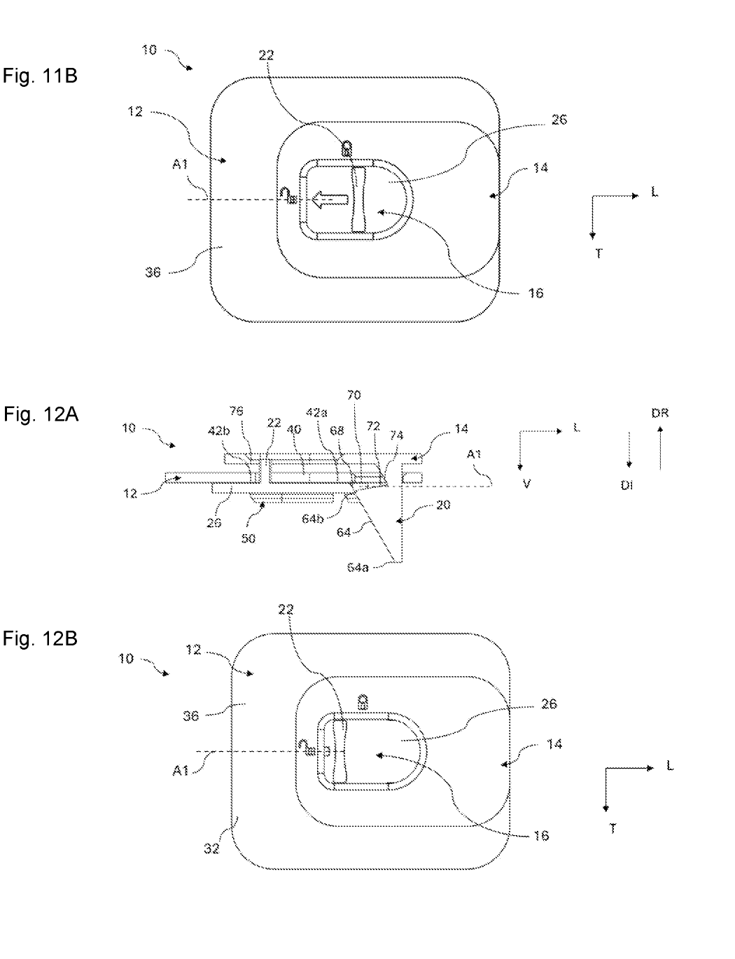

Such a complementarity of shape between the locking member 20 and the bore 44 enables the locking member 20 to be inserted into the main wall 12, at the level of the bore 44 along a vertical V insertion direction DI, seen in FIGS. 11 to 13.

During such an insertion of the locking member 20, it is understood that the connecting wall 60 fits into the base 48 of the U-shape of the bore 44 and that each of the vertical walls 58 fits into one of the branches 46a, 46b of the U-shape of the bore 44.

As particularly seen in FIGS. 6 and 7, each of the vertical walls 58 of the locking member 20 comprises a guide edge 64 which extends in a plane intersecting the longitudinal L and transverse T plane in which the cover 14 extends.

The guide edge 64 of each of the vertical walls 58 extends opposite from the connecting wall 60, with respect to the longitudinal axis L.

An upper end 64a of each of the guide edges 64 and a lower end 64b of each of the guide edges 64 are notably defined, the upper ends 64a being furthest from the cover 14.

More precisely and as seen in FIG. 7, each of the guide edges 64 extends so that a longitudinal dimension DL of each of the vertical walls 58 increases from its upper end 64a towards its lower end 64b.

As can be seen in FIG. 11A, the guide edges 64 are configured to come into contact with the first longitudinal end 26a of the strip 26 when the locking member 20 is inserted into the bore 44 along the insertion direction DI, when the locking device 16 is in its closed position, i.e. in the decompressed state of the spring 24.

The guide edges 64 of the vertical walls 58 of the locking member 20 are thus inclined such that as the locking member 20 is inserted into the bore 44 in the direction of insertion DI, the guide edges 64 form an inclined guide zone which will move the strip 26 transversely along its main axis of elongation A1, such that the spring 24 moves from its decompressed state to its compressed state.

As shown in FIGS. 2, 3 and 11A, the first longitudinal end 26a of the strip 26 comprises a longitudinal recess 66 delimiting a zone for receiving the locking member 20.

More precisely, the recess 66 in the first longitudinal end 26a of the strip 26 is delimited by at least one beveled edge 68 intended to come into contact with the guide edges 64 of the vertical walls 58 of the locking member 20 when the latter is inserted into the bore 44.

Thus and as seen in FIG. 11A , the beveled edge 68 of the recess 66 in the first longitudinal end 26a of the strip 26 is inclined in a plane intersecting the common plane in which the actuator 18 extends so as to present an inclination complementarity with the inclined plane of the guide edges 64 of the vertical walls 58.

In other words, the beveled edge 68 of the first longitudinal end 26a of the strip 26 and the guide edges 64 extend in inclined planes parallel to each other.

This thus ensures planar contact between the inclined edge 68 and the guide edges 64 facilitating the translational movement of the strip 26 along its main axis of elongation A1 and thus the compression of the spring 24.

As can be seen in FIGS. 2 and 3, the recess 66 in the first longitudinal end 26a of the strip 26 is configured such that lateral guide appendages 70 remain which extend longitudinally on either side of the beveled edge 68.

The lateral guide appendages 70 extend so as to laterally frame the vertical walls 58 of the locking member 20 during and after its insertion into the bore 44.

The lateral guide appendages 70, inter alia, improve the stability of the position of the locking member 20 through the bore 44 by limiting the effects of tilting.

As seen in FIGS. 6 and 7, the vertical walls 58 each comprise a retaining edge 72 and a contact edge 74.

Notably, the contact edge 74 of each of the vertical walls 58 extends from the contact face 56 of the cover 14 and is then extended by the retaining edge 72, itself extended by the guide edge 64.

The contact edge 74 of each of the vertical walls 58 extends in a plane parallel to the plane of the guide edge 64.

It is then understood that the contact edge 74 extends in a plane of complementary inclination with the beveled edge 68 of the recess 66 of the first longitudinal end 26a of the strip 26, as previously mentioned.

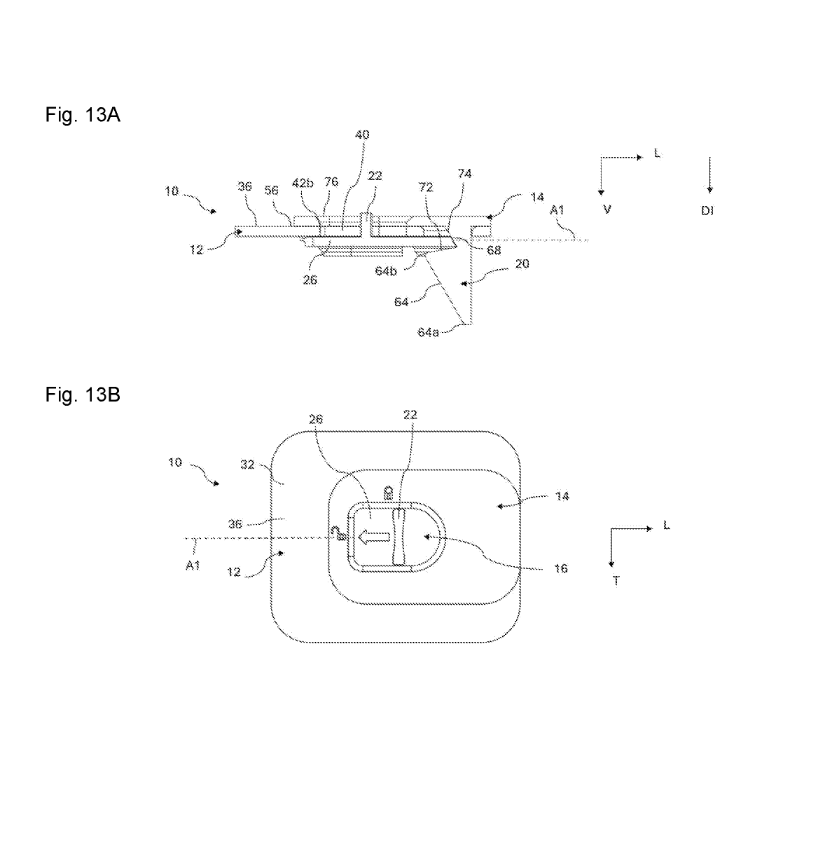

The contact edge 74 of each of the vertical walls 58 is thus configured to form a longitudinal abutment of the first longitudinal end 26a of the strip 26 when the cover 14 is assembled with the main wall 12 and the actuating rib 22 is in the closed position of the locking device 16, as seen in FIG. 13A.

In other words, in the closed position of the locking device 16, when the spring 24 is in its maximum decompression state and the cover 14 is mounted on the main wall 12 as seen in FIG. 13A, the beveled edge 68 of the first longitudinal end 26a of the strip 26 is in planar contact with the contact edge 74 of each of the vertical walls 58 of the locking member 20.

Furthermore and as seen in FIG. 7, the retaining edge 72 extends in a plane intersecting the planes of the guide edge 64 and of the contact edge 74, such that it forms a guide ramp from the beveled edge 68 of the first longitudinal end 26a of the strip 26, towards the contact edge 74.

In other words, the retaining edge 72 of each of the vertical walls 58 extends from the lower end 64b of the guide edge 64 towards the contact edge 74 and such that it generates a positive slope in a longitudinal L and vertical V plane of the locking member 20 from the lower end 64b towards the contact edge 74.

Thus, during the insertion of the locking member 20 into the bore 44, when the guide edges 64 of the vertical walls 58 have moved the actuating rib 22 into the open position of the locking device as seen in FIGS. 12A and 12B, the positive inclination of the retaining edge 72 facilitates on the one hand the elastic return of the spring 24 so as to move the strip 26 carrying the actuating rib 22 into the closed position of the locking device, and on the other hand improves the pressing of the cover 14 against the main wall 12.

Notably, the inclination of the retaining edge 72 allows the cover 14 to be automatically moved vertically towards the base 32 of the main wall when the spring 24 elastically returns from its compressed position seen in FIG. 12A to its decompressed position seen in FIG. 13A.

In other words, contact is guaranteed between the outer face 36 of the base 32 of the main wall 12 and the contact face 56 of the cover 14, as seen in FIG. 13A.

It is therefore understood that when the locking device 16 is in its closed position with the locking member 20 inserted in the bore 44 as seen in FIGS. 8, 13A and 13B, the strip 26 extends so as to overlap the retaining edge 72 and so that its beveled edge 68 is in planar contact with the contact edge 74 of the vertical walls 58.

It is understood that when the beveled edge 68 of the first longitudinal end 26a of the strip 26 is in contact with the contact edge 74, the locking member 20 is locked vertically in position by the retaining edge 72 locked by the strip 26.

As seen in FIG. 6, the cover 14 comprises a complementary aperture 76 configured to extend opposite the aperture in the base of the main wall when the cover 14 is assembled with the main wall.

The complementary aperture 76 then comprises a complementary shape to the aperture 40.

It is then understood that when the cover 14 is assembled with the main wall, the actuating rib 22 also extends through the complementary aperture 76 so as to be accessible to a user.

The cover 14 also comprises two lugs 78 projecting from the contact face 56 on both sides of the complementary aperture 76 and so that they cooperate with the lateral orifices 43 in the base 32 seen in FIG. 5.

The lugs 78 may then comprise a passage for a sealing device of the locking device, not shown herein.

It should also be noted that the use of the sealing device is optional. Thus, in the case where the use of a sealing device is not required, the cap assembly is devoid of lateral orifices and lugs as described hereinbefore.

As seen in FIGS. 1A and 1B, the base 32 of the main wall 12 can be formed in a recess in the main wall 12 of complementary shape to the cover 14.

In other words, the recess forming the base 32 of the main wall 12 can receive the cover 14 in such a way that their cooperation generates a planar surface, with no thickening formed by the superimposition of the cover 14.

A method for assembling the cap assembly 10 will now be described with reference to FIGS. 9 to 13B.

It should be borne in mind that the assembly method is described with the cap assembly 10 of which the actuator 18 comprises two springs 24, but that the same assembly method applies to an actuator 18 comprising a single spring 24.

According to a preferred embodiment, the cap assembly 10 is obtained by an injection molding process.

Also, FIG. 9 shows the main wall 12 carrying the actuator 18 at the end of the injection operation wherein the actuator 18 is in a raised position with respect to the base 32 of the main wall 12.

Notably, the springs 24 are secured to the base 32 by means of the elastic hinges 38 described previously.

Thus, prior to assembling the cap assembly 10, a preparatory step is necessary.

More precisely, the preparatory step is carried out directly in the factory after the main wall 12 has been injection-molded.

The preparatory step notably consists in pivoting the actuator 18 about a hinge axis C2, herein transverse T, so as to move the actuator 18 against the base 32 of the main wall 12.

Specifically, in the preparatory step, the actuator 18 is pivoted such that the actuating rib 22 extends through the aperture 40 of the base 32 and that the actuator 18 is locked in position against the base 32 by means of the retaining members 50, as described previously.

In other words, the preparatory step consists in clipping the actuator 18 against the base 32 of the main wall 12 by means of the retaining members 50.

At the end of the preparatory step, it is understood that the actuating rib 22 extends through the aperture 40 in the closed position of the locking device 16 and that the springs 24 are in their decompressed position, as seen in FIGS. 10A and 10B.

Once the preparatory step has been completed, a first step of the assembly method seen in FIG. 11A is implemented, during which a user inserts the locking member 20 carried by the cover 14 into the bore 44 of the base 32, exerting a force along the insertion direction DI.

In this first step, the connecting wall is positioned opposite the base 48 of the U-shape of the bore 44 and the vertical walls 58 are positioned opposite the branches of the U-shape of the bore 44.

Also, the lugs 78 are positioned opposite the lateral orifices 43.

It is understood from the foregoing that when the locking member 20 is inserted into the bore 44, the guide edges 64 come into contact with the beveled edge 68 of the strip 26.

Thus, as the locking member 20 is inserted into the bore 44 in the direction of insertion DI, as seen in FIG. 11A, the strip 26 is displaced along its main axis of elongation A1 and such that the springs gradually compress along their respective axis of compression.

As seen in FIG. 12A, when the locking member 20 is inserted into the bore 44 such that the beveled edge 67 is level with the lower end 64b of the guide edge 64, the actuating rib 22 reaches the end of its travel and is in the open position of the locking device 16, as seen in FIG. 12B, and the springs are in their state of maximum compression.

A second step of the method is implemented.

Notably, the second step consists in an automatic movement of the strip 26 when its beveled edge 68 exceeds the lower end 64b of the guide edge 64, so that the actuating rib 22 automatically moves into the closed position of the locking device 16, as seen in FIG. 13A.

More precisely, under the elastic return effect of the springs into their decompressed state and by means of the retaining edges 72 of the vertical walls 58 forming guide ramps for the beveled edge 68 of the strip 26, the actuating rib 22 moves automatically into the closed position of the locking device 16.

In other words, when the locking member 20 is inserted into the bore 44 such that the beveled edge 68 of the strip 26 protrudes beyond the lower end 64b of the guide edges 24, the inclination of the retaining strips 72 combined with the elastic return effect of the springs 24 towards their decompressed state automatically brings the actuating rib 22 into the closed state of the locking device 16 by sliding the beveled edge 68 against the retaining edges 72.

As previously mentioned, during the second step, the contact face 56 of the cover 14 is pressed against the outer face 36 of the base 32 of the main wall 12.

It is understood that at the end of the second step, the beveled edge 68 translates along the retaining edge 72 until it comes into planar contact with the contact edge 74, and as seen in FIG. 13A .

At the end of the second step and as seen in FIGS. 13A and 13B, the actuating rib 22 is in the closed position of the locking device 16 such that the strip 26, the beveled edge 68 of which is in contact with the contact edge 74, holds the locking member 20 in the bore 44, forming a vertical abutment for the retaining edges 72.

In other words, at the end of the second step, the cover 14 is locked in position on the main wall 12 by means of the locking device 16 in its closed position.

In the event that the user wishes to unlock the locking device 16 in order to detach the cover 14 from the main wall 12, for example for a maintenance operation on the electric meter installation, a third step can be implemented.

During the third step, the user moves the actuating rib 22 against the second edge 42b of the aperture 40, as seen in FIG. 12B, so as to compress the springs and position the locking device 16 in its open position.

It is understood that at the end of the third step, the strip 26 is moved in translation along its main axis of elongation A1 so that the beveled edge 68 moves longitudinally away from the contact edge 74.

Thus and as seen in FIG. 12A , at the end of the third step, the locking device 16 is in the open position thereof and the retaining edge 72 is uncovered by the strip 26.

In this way, at the end of the third step, the user can freely withdraw the cover 14 in a withdrawal direction DR, opposite the direction of insertion DI, while continuing to hold the actuating rib 22 in the unlocked state of the locking device 16.

Once the locking member 20 has been withdrawn from the bore 44, the user can release the actuating rib 22 so that the elastic return of the springs 24 returns the actuating rib 22 into the closed position of the locking device 16 and decompressed state of the springs, as seen in Figures 10A and 10B.

It is understood that at the end of the fourth step, the user can carry out the second step of the method again, for example to reposition the cover 14 on the main wall 12 after the maintenance operation on the electric meter installation.

The advantage of the invention as described above is that it enables a cover to be easily secured to a main wall without needing to use a third part such as a screw, while at the same time enabling at least partial automatic detaching and securing. In addition, the invention makes it possible to secure and detach a cover to a main wall without needing to use tools such as for example a screwdriver.

In addition, the invention as just described is advantageous in that it enables two plastic-injected parts to be secured without the need for a third part and the assembly and disassembly process can be carried out with one-hand by a user.

1. A cap assembly comprising a main wall and a cover, adapted to cooperate with each other, the cap assembly comprising a locking device configured to lock the cover in position on the main wall, the locking device comprising at least:
- an actuator on the main wall and comprising at least one actuating rib and at least one elastically deformable member translationally linked to each other,
the actuating rib extending through a through-aperture formed in the main wall, and
the actuator being movable in translation with respect to the main wall so that the actuating rib moves through the aperture between a closed position of the locking device wherein the elastically deformable member is in a decompressed state, and an open position of the locking device wherein the elastically deformable member is in a compressed state,
- a locking member projecting from the cover and configured at least to lock said cover in position with respect to the main wall when the actuating rib of the actuator is in the closed position of the locking device.

2. The cap assembly according to claim 1, wherein the actuator comprises a strip from which the actuating rib projects, the strip being integral with the elastically deformable member by at least one retaining arm extending transversely from the strip, the elastically deformable member being integral with the retaining arm.

3. The cap assembly according to claim 1, wherein at least two retaining members project from the main wall and so as to lock the actuator in position against the main wall and to allow translational movement of the actuator with respect to the main wall.

4. The cap assembly according claim 1, wherein the main wall comprises a through-bore configured to receive the locking member.

5. The cap assembly according to claim 4, wherein the locking member comprises at least one guide edge extending in a plane intersecting a common plane (P1) of the actuator, the at least one guide edge being configured to move the actuating rib from the closed position of the locking device to the open position of the locking device when the locking member is inserted into the bore.

6. The cap assembly according to claim 5, wherein the locking member comprises at least one retaining edge configured to automatically move the actuating rib from the open position of the locking device to the closed position of the locking device when the locking member is inserted into the bore, so as to lock the cover in position with respect to the main wall.

7. The cap assembly according to claim 5, wherein the strip comprises a beveled edge configured to be in planar contact with the at least one guide edge of the locking member when the locking member is inserted into the through-bore.

8. The cap assembly according to claim 7, wherein the locking member comprises at least one contact edge configured to be in planar contact with the beveled edge of the strip when the locking member is inserted into the through-bore and the actuating rib is in the closed position of the locking device.

9. The cap assembly according to claim 1, wherein the cover comprises a complementary aperture configured to extend facing the aperture of the main wall when the cover is assembled on the main wall and so that the actuating rib extends through the complementary aperture.

10. The cap assembly according to claim 1, wherein the actuator is pivotally mounted with respect to the main wall by means of at least one elastic hinge extending between the at least one elastically deformable member and the main wall, and so that the actuator is capable of pivoting about a hinge axis with respect to the main wall.

11. The cap assembly according to claim 1, wherein the actuator is integral with the main wall and the locking member is integral with the cover.

12. The cap assembly according to claim 1, obtained by a plastic injection process.

13. An electric meter installation comprising an electric meter and at least one cap assembly according to claim 1.
